(19) United States
(12) Patent Application Publication
(10) Pub. No.: US 2012/0006397 A1
(43) Pub. Date: Jan. 12, 2012

(54) INTEGRATED SOLAR ROOF TILE AND METHOD FOR PRODUCING THE SAME

(75) Inventors: TAI-MING GOU, Tu-Cheng (TW); HUI-MING LU, Tu-Cheng (TW)

(73) Assignee: HON HAI PRECISION INDUSTRY CO., LTD., Tu-Cheng (TW)

(21) Appl. No.: 12/889,432

(22) Filed: Sep. 24, 2010

(30) Foreign Application Priority Data
Jul. 7, 2010 (CN) 201010219690.1

(51) Int. Cl. H01L 31/0352; H01L 31/18

(52) U.S. Cl. 136/256; 438/64; 257/E31.032

(57) ABSTRACT

A integrated solar roof tile includes a curved substrate, a silicon-nitride (SiN) film, a first electrode, an amorphous silicon film, a second electrode, a conducting wire layer and a protecting film. The curved substrate includes a top surface and a cross-sectional surface. The SiN film covers the top surface of the curved substrate. The first electrode is disposed on the SiN film. The amorphous silicon film covers the SiN film and the first electrode. The second electrode is disposed on the amorphous silicon film and electrically insulating from the first electrode. The conducting wire layer covers the amorphous silicon film and is electrically connected to the second electrode. The protecting film covers on the conducting wire layer.

### BACKGROUND

1. Technical Field

The present disclosure generally relates to solar roof tiles, and more particularly to an integrated solar roof tile and method for producing the same.

2. Description of Related Art

Photovoltaic or solar modules are usually equipped with a frame constructed of, for example, aluminum to improve rigidity of the modules, and also to provide a convenient means to install the modules to, such as a roof. The solar modules with the frame are bolted or clamped onto separate support structures, e.g. racks. Subsequently the support structures are securely bolted or screwed directly into the roof. Such installed modules are exposed to the sun to transform solar energy into electrical power.

However, complicated structures and high producing and installation cost affix popularity of the roof and the solar module.

Therefore, a need exists in the industry to overcome the described problem.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded view of an integrated solar roof tile of an exemplary embodiment of the disclosure.

FIG. 2 is a partial perspective view of the integrated solar roof tile of FIG. 1.

FIG. 3 is a schematic view of an amorphous silicon film partially enlarged of the integrated solar roof under sun's ray of FIG. 1.

FIG. 4 is a flowchart of one embodiment of a method of producing the integrated solar roof tile of an exemplary embodiment of the disclosure.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

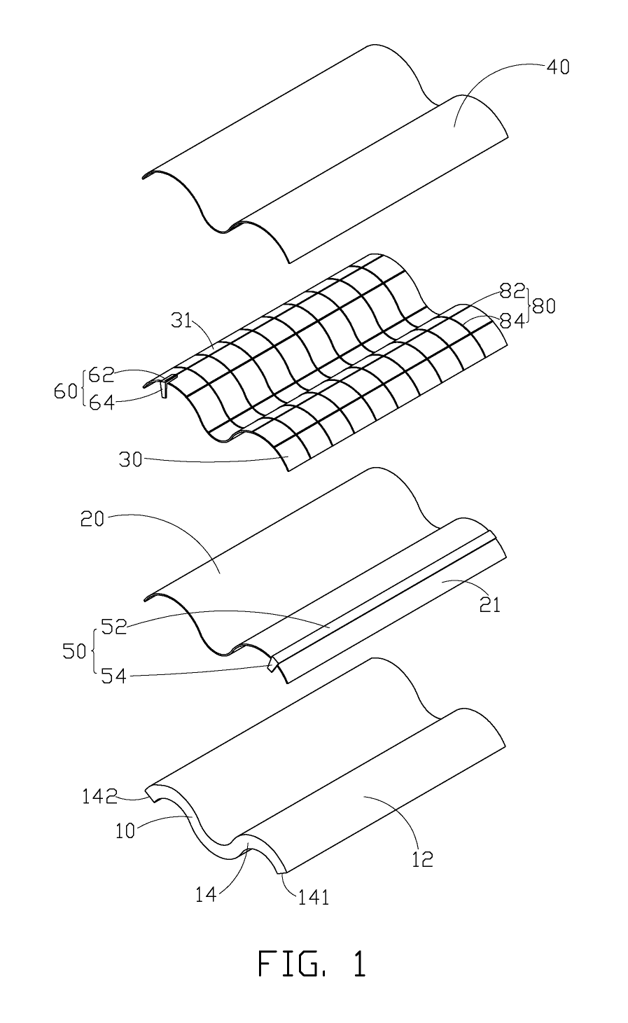

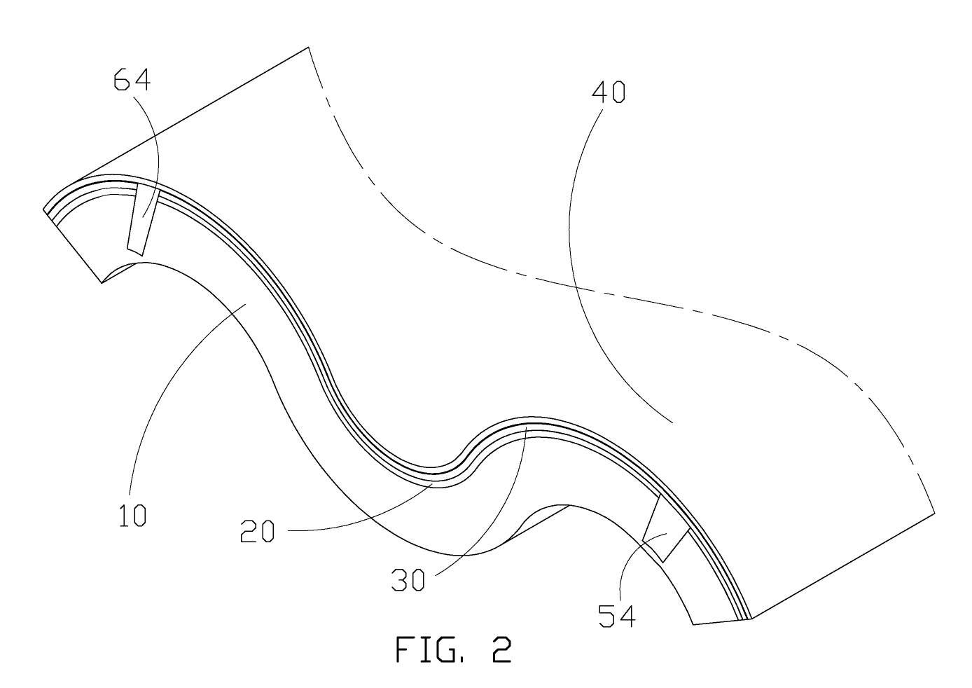

Referring to FIG. 1 and FIG. 2, an integrated solar roof tile of an exemplary embodiment of the disclosure comprises a curved substrate 10, a silicon-nitride (SiN) film 20, a first electrode 50, an amorphous silicon film 30, a second electrode 60, a conducting wire layer 80 and protecting film 40. The curved substrate 10 comprises a top surface 12 and a cross-sectional surface 14. In this embodiment, the curved substrate 10 is made of electrically insulating materials, such as ceramic, clay, or concrete materials. The SiN film 20 is configured on the top surface 12 by a coating process and defines a top surface 21 away from the curved substrate 10.

The first electrode 50 is disposed on the top surface 21 of the SiN film 20, and comprises a first body 52 and a first head portion 54. The first body 52 is shaped like a strip and extends across the top surface 21 of the SiN film 20. The first head portion 54 perpendicularly extends from the first body 52 towards the curved substrate 10 along the cross-sectional surface 14. In this embodiment, the first head portion 54 is affixed to the top surface 21 of the SiN film 20. The amorphous silicon film 30 covers the SiN film 20 and the first electrode 50 by a coating process.

The second electrode 60 is disposed on the amorphous silicon film 30 and comprises a second body 62 and a second head portion 64. The second body 62 is disposed on a top surface 31 of the amorphous silicon film 30. The second head portion 64 perpendicularly extends from the second body 62 passing through the amorphous silicon film 30 and the SiN film 20, and arrives at the cross-sectional surface 14 of the curved substrate 10. In this embodiment, the second body 62 is affixed to the top surface 31 of the amorphous silicon film 30.

The first electrode 50 and the second electrode 60 are electrically insulated from each other to be used as two electrodes of the integrated solar roof tile. The first head portion 54 and the second head portion 64 are respectively close to two opposite edges 141, 142 of the cross-sectional surface 14 of the curved substrate 10, and used as two connecting ports to connect with junction boxes.

The conducting wire layer 80 covers the top surface 31 of the amorphous silicon film 30 and electrically connects to the second electrode 60. In this embodiment, the conducting wire layer 80 comprises a plurality of vertically wires 82 and a plurality of horizontally wires 84 which are electrically connected together. One of the vertically wires 82 is connected to the second body 62 of the second electrode 60. In this way, the conducting wire layer 80 is electrically connected to the second electrode 60.

In summary, the first electrode 50, the amorphous silicon film 30, the second electrode 60 and the conducting wire layer 80 cooperatively form a solar cell layer of the integrated solar roof tile.

The protecting film 40 covers on the conducting wire layer 80. In this embodiment, the protecting film 40 is transparent for sun rays easily penetrating therethrough. The protecting film 40 comprises an Ethylene Vinyl acetate (EVA) layer and an Ethylene Tetrafluoroethylene (ETFE) layer, and the EVA layer is located between the ETFE layer and the conducting wire layer 80.

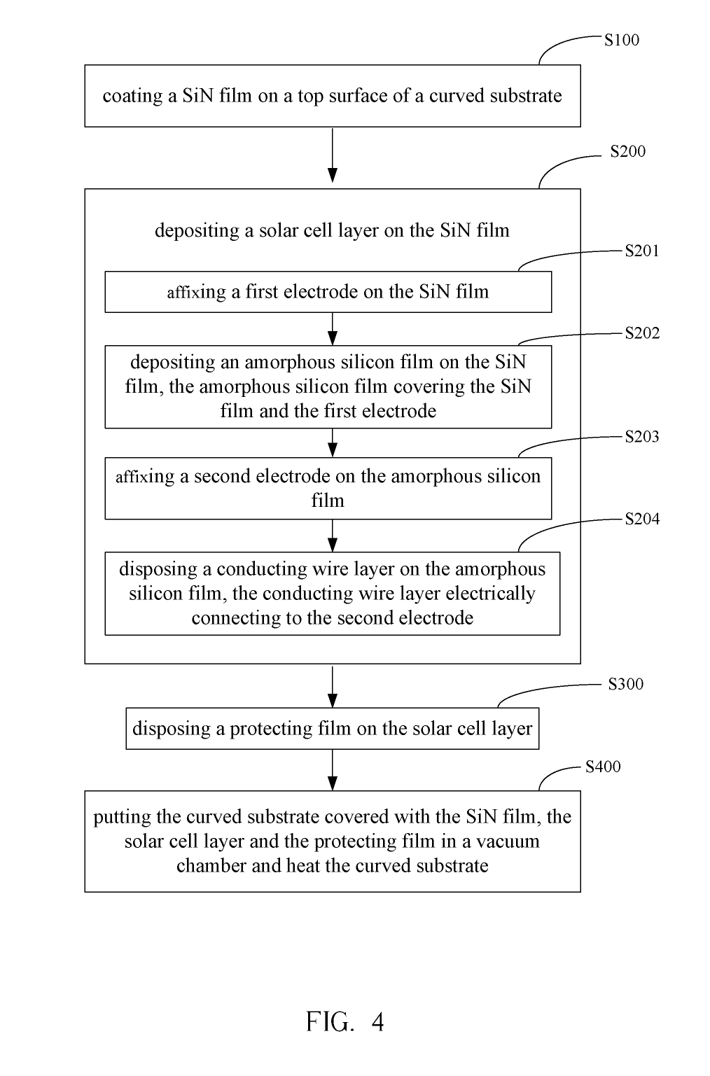

FIG. 4 is a flowchart of one embodiment of a method of producing the integrated solar roof tile. The integrated solar roof tile is made based on the curved substrate 10, such as ceramic tile, clay tile or concrete tile, which is made of electrically insulating materials. The method is described as follow.

In block S100, coat the SiN film 20 on the top surface 12 of the curved substrate 10. In this embodiment, the SiN film 20 is coated by a Plasma-enhanced chemical vapor deposition (PECVD) device. The process of coating the SiN film 20 comprises steps as follow: cleaning the curved substrate 10, coating the SiN film 20 and a heat treatment process.

The step of cleaning the curved substrate 10 comprises: cleaning the curved substrate 10 in acetone liquid after immersing in glass lotion for more than ten hours, cleaning the curved substrate 10 in absolute alcohol and drying the curved substrate 10.

The step of coating the SiN film 20 comprises: putting the cleaned curved substrate 10 into a vacuum chamber of the PECVD device, heating the vacuum chamber to 300° C. and maintaining the temperature, introducing an atmosphere mixture comprising N2, SiH4 and NH3, generating radio frequency power with density of about 0.25 W/cm2 and discharging. In this embodiment, the flux radio of SiH4 and NH3 is 30:5. The SiN film 20 is deposited for 20-35 minutes and redeposited for 30-45 minutes.

The step of heat treatment process comprises putting the curved substrate 10 coated with the SiN film 20 into an oven, introducing N2 into the oven, heating the oven to 280° C., maintaining the temperature for 4 hours, and cooling the oven to room temperature.

In block S200, deposit the solar cell layer, which is cooperatively formed by the first electrode 50, the amorphous silicon film 30, the second electrode 60 and the conducting wire layer 80, on the SiN film 20. Depositing the solar cell layer comprises steps as follow.

Firstly, in block S201, affix the first electrode 50 on the top surface 21 of the SiN film 20. The first body 52 is shaped like a strip and extends across the top surface 21 of the SiN film 20, and the first head portion 54 perpendicularly extends from the first body 52 towards the curved substrate 10 along the cross-sectional surface 14.

Secondly, in block S202, deposit the amorphous silicon film 30 on the top surface 21 of the SiN film 20. The amorphous silicon film 30 covers the SiN film 20 and the first electrode 50. In this embodiment, the amorphous silicon film 30 is deposited in a vacuum chamber of a Plasma-enhanced chemical vapor deposition (PECVD) device. The method of depositing amorphous silicon film 30 comprises steps as follow.

Deposit a positive(p)-doped layer 32 on the top surface 21 of the SiN film 20 by use of an atmosphere of 25 SCCM of B2H6, 25 SCCM of CH4 and 40 SCCM of SiH4 with radio frequency power at 100 W. The curved substrate 10 is maintained at 100° C. The air pressure in the vacuum chamber is maintained at 1 Pa. The process of depositing the p-doped layer 32 is maintained for 1 minute.

Deposit an intrinsic semiconductor (i)-doped layer 34 on the p-doped layer 32 by use of an atmosphere of 20 SCCM of SiH4 with radio frequency power at 100 W. The curved substrate 10 is maintained at 200° C. The air pressure in the vacuum chamber is maintained at 1 Pa. The process of depositing the i-doped layer 34 is maintained for 45 minutes.

Deposit a negative (n)-doped layer 36 on the i-doped layer 34 by use of an atmosphere of 30 SCCM of PH3 and 15 SCCM of SiH4 with radio frequency power at 100 W. The curved substrate 10 is maintained at 250° C. The air pressure in the vacuum chamber is maintained at 1 Pa. The process of depositing the n-doped layer 34 is maintained for 1.5 minutes.

In block S203, affix the second electrode 60 on the top surface 31 of the amorphous silicon film 30. The first electrode 50 and the second electrode 60 are electrically insulated with each other to be used as two electrodes of the integrated solar roof tile.

In block S204, dispose the conducting wire layer 80 on the top surface 31 of the amorphous silicon film 30. In this embodiment, the conducting wire layer 80 comprises a plurality of vertically wires 82 and a plurality of horizontally wires 84 which are electrically connected together. One of the vertically wires 82 is connected to the second body 62 of the second electrode 60. In this way, the conducting wire layer 80 is electrically connected to the second electrode 60.

In block S300, dispose the protecting film 40 on the conducting wire layer 80. In this embodiment, the protecting film 40 is transparent for sun rays easily penetrating therethrough. The EVA layer of the protecting film 40 is located between the ETFE layer of the protecting film 40 and the conducting wire layer 80.

In block S400, put the curved substrate 10 covered with the SiN film 20, the solar cell layer and the protecting film 40 in a vacuum chamber and heat the curved substrate 10 to be configured as a integrated structure.

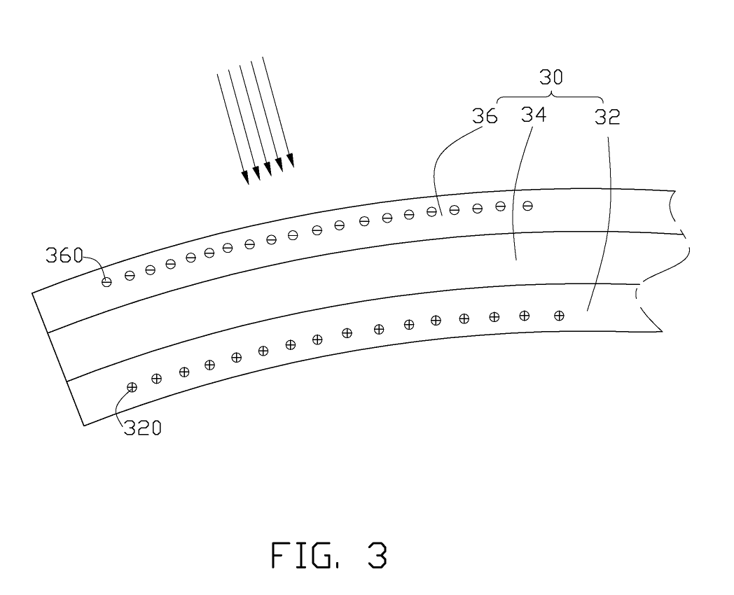

Referring to FIG. 3, when sun rays are transmitted onto the integrated solar roof tile, the sun rays penetrate the protecting film 40 and are transmitted onto the amorphous silicon film 30. In this condition, free electrons on the n-doped layer 36 rush into the p-doped layer 32 to fill the free holes on the p-doped layer 32, thereby the n-doped layer 36 comprising a plurality of negative electric charges 360 and the p-doped layer 32 comprising a plurality of positive electricity charges 320. Therefore, an electric field is formed in the integrated solar roof tile.

The conducting wire layer 80 gathers the negative electric charges 360 and transmits the negative electric charges 360 to the second electrode 60. The integrated solar roof tile has a high efficiency of converting solar energy into usable electric current due to the conducting wire layer 80 gathering and transmitting the electric charges 360.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

What is claimed is:

1. An integrated solar roof tile, comprising
a curved substrate, comprising a top surface and a cross-sectional surface;
a silicon-nitride (SiN) film, configured on the top surface of the curved substrate;
a first electrode, disposed on the SiN film;
an amorphous silicon film, covering the SiN film and the first electrode;
a second electrode, disposed on the amorphous silicon film and electrically insulated from the first electrode;
a conducting wire layer, covering the amorphous silicon film and electrically connected to the second electrode; and
a protecting film covering on the conducting wire layer.

2. The integrated solar roof tile as claimed in claim 1, wherein the first electrode comprises a first body and a first head portion, the first body extends across the top surface of the SiN film and the first head portion perpendicularly extends from the first body towards the curved substrate along the cross-sectional surface.

3. The integrated solar roof tile as claimed in claim 2, wherein the second electrode comprises a second body and a second head portion, the second head portion perpendicularly extending from the second body, passing through the amorphous silicon film and the SiN film, and arriving at the cross-sectional surface of the curved substrate.

4. The integrated solar roof tile as claimed in claim 3, wherein the conducting wire layer comprises a plurality of vertically wires and a plurality of horizontally wires, the vertically and horizontally wires are electrically connected to the second body of the second electrode.

5. The integrated solar roof tile as claimed in claim 4, wherein the protecting film is transparent for sun rays easily penetrating therethrough.

6. The integrated solar roof tile as claimed in claim 5, wherein the protecting film comprises an Ethylene Vinyl Acetate (EVA) layer and an Ethylene Tetrafluoroethylene (ETFE) layer, and the EVA layer is located between the ETFE layer and the conducting wire layer.

7. A method of producing an integrated solar roof tile, the integrated solar roof tile comprising a curved substrate comprising a top surface and a cross-sectional surface, the method comprising:
coating a SiN film on the top surface of the curved substrate;
forming a solar cell layer on the SiN film, comprising:
affixing a first electrode on the SiN film;
depositing a amorphous silicon film on the SiN film, the amorphous silicon film covering the SiN film and the first electrode;
affixing a second electrode on the amorphous silicon film, the first electrode and the second electrode electrically insulated with each other to be used as two electrodes of the integrated solar roof tile; and
disposing a conducting wire layer on the amorphous silicon film, the conducting wire layer electrically connected to the second electrode;
disposing a protecting film on the solar cell layer; and
putting the curved substrate covered with the SiN film, the solar cell layer and the protecting film in a vacuum chamber and heat the curved substrate to be configured as a integrated structure.

8. The method of producing the integrated solar roof tile as claimed in claim 7, wherein the step of coating the SiN film on the top surface of the curved substrate comprises cleaning the curved substrate, coating the SiN film and heat treatment process.

9. The method of producing the integrated solar roof tile as claimed in claim 8, wherein the step of depositing the amorphous silicon film comprises:
depositing a positive(p)-doped layer on the SiN film;
depositing an intrinsic semiconductor (i)-doped layer on the p-doped layer; and
depositing a negative (n)-doped layer on the i-doped layer.
